(19) United States
(12) Patent Application Publication
(10) Pub. No.: US 2026/0182105 A1
(43) Pub. Date: Jun. 25, 2026

(54) ELEMENT TRANSCRIPTION METHOD AND ELEMENT TRANSCRIPTION DEVICE

(71) Applicant: Panasonic Intellectual Property Management Co., Ltd., Osaka (JP)

(72) Inventors: JUNICHI KAMATANI, Nara (JP); TOMOTAKA FURUTA, Osaka (JP)

(21) Appl. No.: 19/537,610

(22) Filed: Feb. 12, 2026

Related U.S. Application Data
(63) Continuation of application No. PCT/JP2024/036165, filed on Oct. 9, 2024.

(30) Foreign Application Priority Data
Nov. 21, 2023 (JP) 2023-197489

(51) Int. Cl. H10H 29/02; H10P 72/50; H10P 72/70; H10P 95/60

(52) U.S. Cl. CPC H10H 29/02; H10P 72/53; H10P 72/7434; H10P 95/60

(57) ABSTRACT

In an element transfer method, target substrate (2) and stamp (3) are brought relatively close to each other to bring the target substrate and element (10) into contact with each other, and the target substrate and the stamp are relatively separated while vibration is applied to the stamp and the element by vibrator (80), so that the element is transferred from the stamp to the target substrate.

### TECHNICAL FIELD

The present disclosure relates to an element transfer method and an element transfer device.

### BACKGROUND ART

In recent years, utilization of light has been explored in the fields of high-speed communication, large-capacity communication, and sensing. In particular, a technology called “silicon photonics” has been attracting attention. Silicon photonics is a technology for forming an optical circuit on a silicon substrate using a complementary metal oxide semiconductor (CMOS) process, in the same manner as for semiconductor electronic circuits. The optical circuit formed by silicon photonics is a circuit having a fine size having a light control function, and an optical input unit/output unit, an optical modulator, and the like are formed. These elements are connected to one another using an extremely fine optical waveguide, which is in the order of submicron. Usually, when an optical circuit is caused to function, it is necessary to connect light from a light source such as an LD to an optical input unit with high accuracy via an external transmission body such as an optical fiber. However, by arranging an LD chip or an optical element itself directly on an optical circuit board and optically connecting the LD chip or the optical element, it is possible to cause the optical circuit to function with space saving and a small number of components.

Similarly, there is a micro LED display as a device in which a microchip needs to be arranged. Conventionally, when manufacturing a micro LED display, a method has been adopted in which a plurality of micro LEDs formed by singulating a wafer is arranged on a circuit board one by one by a pick-and-place process. In such a manufacturing method, since the pick-and-place process needs to be repeated several tens of thousands of times or more, the process takes time and the manufacturing cost increases.

Patent Literature 1 discloses a method of transferring a plurality of elements to a target substrate by one pick-and-place process using a temporary holding member such as an adhesive stamp. Therefore, the time required for the process can be shortened, and the manufacturing cost can be reduced.

In a case where such a holding member has weak adhesive force for holding the element, the held element falls off from the holding member, so that the element is not transferred to a desired position on the target substrate, and an operation failure may occur. Therefore, the holding member is required to have strong adhesive force for holding the element. On the other hand, when the holding member has too strong adhesive force for holding the element, the held element is not transferred onto the target substrate and remains held by the holding member. As a result, the element is not transferred to a desired position on the target substrate, and an operation failure occurs. In addition, if the pick-and-place process proceeds while the element remains on the holding member, the element on the substrate and the element remaining on the holding member collide with each other, and the element is damaged.

Therefore, Patent Document 1 also discloses a method of facilitating the transfer of the element by plasma treatment of the target substrate contact surface of the element, or a method of facilitating the transfer of the element by reducing the adhesive force of the holding member by heat treatment.

### CITATION LIST

### Patent Literature

PTL 1: Japanese U.S. Pat. No. 6,453,437

### SUMMARY OF THE INVENTION

In the conventional technique disclosed in Patent Literature 1, an expensive device for generating plasma is required, and the optical element may fall off during plasma processing. In addition, the optical element, the holding member, and the target substrate are not transferred to a desired position due to a difference in thermal expansion coefficient among the optical element, the holding member, and the target substrate due to the heat treatment. That is, a relative positional deviation between the element and the target substrate may occur. Furthermore, the heat treatment cycle may cause deterioration of the holding member.

An object of non-limiting examples of the present disclosure is to provide an element transfer method and an element transfer device capable of preventing the element from falling off and remaining on a stamp and realizing highly accurate and reliable transfer of the element by reducing the adhesive force at the time of transferring the element with a simple configuration.

An element transfer method according to one aspect of the present disclosure includes:
aligning positions of a target substrate and an element picked up by an adhesive force of a stamp;
bringing the target substrate and the stamp relatively close to each other to bring the target substrate and the element into contact with each other; and
transferring the element from the stamp to the target substrate by relatively separating the target substrate and the stamp while applying vibration to the stamp and the element by a vibrator.

An element transfer device according to one aspect of the present disclosure includes:
a target substrate installation base on which a target substrate is installed;
a stamp head including a stamp configured to pick up an element with adhesive force;
a frame that holds the stamp head in which the stamp faces the target substrate installation base;
a substrate position adjustment mechanism configured to adjust a position of the target substrate with respect to the stamp and bring the target substrate and the stamp relatively close to each other and separates the target substrate and the stamp;
an imaging unit configured to capture an image of the element and the stamp and capture an image of the element and the target substrate, to enable detection of a positional deviation amount between the element and the stamp and a positional deviation amount between the element and the target substrate, respectively;
a contact detector configured to detect contact between the element and the target substrate;
a vibrator that is disposed between the contact detector and the frame and configured to apply vibration to the stamp and the element; and
a controller configured to control the vibrator and the substrate position adjustment mechanism so as to transfer the element from the stamp to the target substrate by:
(a) controlling the substrate position adjustment mechanism so as to reduce the positional deviation amounts,
(b) controlling the substrate position adjustment mechanism so as to bring the target substrate and the stamp relatively closer,
(c) detecting that the target substrate and the element are in contact with each other by the contact detector,
(d) controlling the vibrator so as to apply vibration to the stamp and the element, and
(e) relatively separating the target substrate and the stamp while applying vibration to the stamp and the element.

According to the above aspect of the present disclosure, it is possible to provide an element transfer method and an element transfer device capable of realizing highly accurate and reliable transfer of an element by reducing the adhesive force at the time of transferring the element with a simple configuration in which neither plasma treatment nor heat treatment is required, and a vibrator for applying vibration to an element and a stamp is provided to perform vibration.

### BRIEF DESCRIPTION OF THE DRAWINGS

FIG. 1 is a diagram illustrating a configuration example of an element transfer device according to an exemplary embodiment of the present disclosure.

FIG. 2 is a diagram illustrating a stamp head and a vibrator of the element transfer device according to the exemplary embodiment of the present disclosure.

FIG. 3 is a flowchart illustrating an element transfer method according to the exemplary embodiment of the present disclosure.

FIG. 4A is a view for explaining an element transfer method according to the exemplary embodiment of the present disclosure.

FIG. 4B is a view for explaining the element transfer method according to the exemplary embodiment of the present disclosure.

FIG. 4C is a view for explaining the element transfer method according to the exemplary embodiment of the present disclosure.

FIG. 4D is a view for explaining the element transfer method according to the exemplary embodiment of the present disclosure.

FIG. 4E is a view for explaining the element transfer method according to the exemplary embodiment of the present disclosure.

FIG. 4F is a view for explaining the element transfer method according to the exemplary embodiment of the present disclosure.

FIG. 4G is a view for explaining the element transfer method according to the exemplary embodiment of the present disclosure.

### DESCRIPTION OF EMBODIMENTS

Hereinafter, preferred exemplary embodiments of the present disclosure will be described in detail with reference to the drawings. Note that, in the present specification and the drawings, constituent elements having substantially identical functional functions are denoted by the same reference marks, and thus, duplicate description will be omitted. The shape, thickness, length, or the like of constituent members illustrated in the drawings described below are different from those of the actual constituent members. Further, materials of such constituent members are not limited to materials described in the present exemplary embodiment.

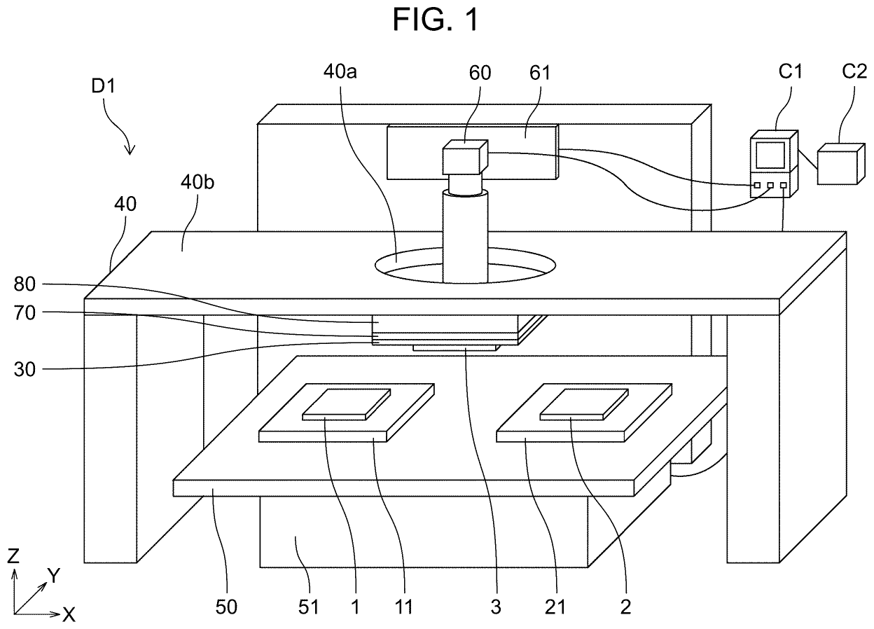

In FIG. 1 and subsequent drawings, an X-axis direction, a Y-axis direction, and a Z-axis direction represent a direction parallel to an X-axis, a direction parallel to a Y-axis, and a direction parallel to a Z-axis, respectively. The X-axis direction and the Y-axis direction are orthogonal to each other. The X-axis direction and the Z-axis direction are orthogonal to each other. The Y-axis direction and the Z-axis direction are orthogonal to each other. An XY plane represents a virtual plane parallel to the X-axis direction and the Y-axis direction. An XZ plane represents a virtual plane parallel to the X-axis direction and the Z-axis direction. A YZ plane represents a virtual plane parallel to the Y-axis direction and the Z-axis direction. In addition, in FIG. 1 and subsequent drawings, a direction indicated by an arrow in the X-axis direction corresponds to a positive X-axis direction, and a direction opposite to the direction corresponds to a negative X-axis direction. In addition, in FIG. 1 and subsequent drawings, a direction indicated by an arrow in the Y-axis direction corresponds to a positive Y-axis direction, and a direction opposite to the direction corresponds to a negative Y-axis direction. In addition, in FIG. 1 and subsequent drawings, a direction indicated by an arrow in the Z-axis direction corresponds to a positive Z-axis direction, and a direction opposite to the direction corresponds to a negative Z-axis direction. The Z-axis direction is equivalent to a vertical direction or an up-down direction, for example, and the X-axis direction and the Y-axis direction are equivalent to horizontal directions or right-left directions, for example.

### First Exemplary Embodiment

Element transfer device

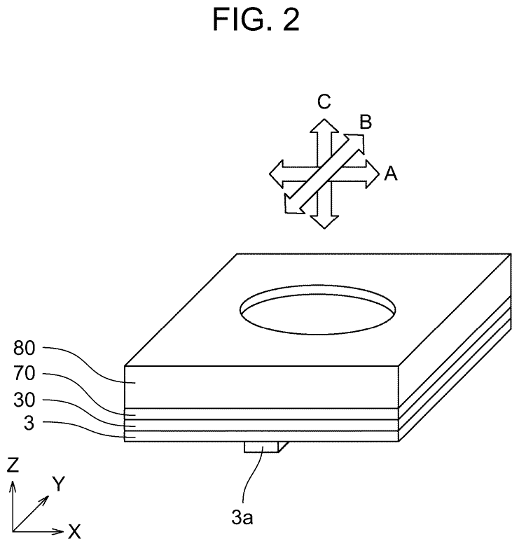

To begin with, element transfer device D1 according to an exemplary embodiment of the present disclosure will be explained with reference to FIGS. 1 and 2. FIG. 1 is a diagram illustrating a configuration example of element transfer device D1 according to the exemplary embodiment of the present disclosure, and FIG. 2 is a diagram illustrating stamp head 30 and vibrator 80 of element transfer device D1 according to the exemplary embodiment of the present disclosure.

Element transfer device D1 includes at least source substrate installation base 11, target substrate installation base 21, stamp head 30, frame 40, substrate position adjustment mechanism 51, imaging unit 60, imaging unit adjustment mechanism 61, contact detector 70, vibrator 80, and controller C1. Element transfer device D1 picks up element 10 from source substrate 1 with the adhesive force of stamp 3, reduces the adhesive force, and then transfers element 10 of stamp 3 to target substrate 2.

Source substrate installation base 11 is, for example, a quadrangular plate-shaped base on which source substrate 1 is installed. Source substrate installation base 11 may be any type as long as source substrate 1 can be installed. Source substrate installation base 11 may be provided with, for example, an adsorption hole for adsorbing source substrate 1, and apply a negative pressure to the adsorption hole to bring source substrate 1 into close contact with source substrate installation base 11.

Here, source substrate 1 is, for example, a quadrangular plate-shaped member, and element 10 is formed on the surface thereof. Element 10 is, for example, an optical element formed on source substrate 1 by a CMOS process. A method for forming element 10 may be any type as long as the element is formed by a method capable of obtaining desired performance. When source substrate 1 and element 10 are picked up from source substrate 1 by stamp 3, alignment marks may be formed for the purpose of aligning stamp 3 and element 10.

Target substrate installation base 21 is, for example, a quadrangular plate-shaped base on which target substrate 2 is installed. The type of target substrate installation base 21 is not limited as long as target substrate 2 can be installed. Target substrate installation base 21 may be provided with, for example, an adsorption hole for adsorbing target substrate 2, and may apply a negative pressure to the adsorption hole to bring target substrate 2 into close contact with target substrate installation base 21.

Here, target substrate 2 is, for example, a quadrangular plate-shaped member, and is a substrate to which element 10 formed on source substrate 1 is transferred on the surface thereof. In target substrate 2, an electric circuit or an optical circuit (not illustrated) may be formed so as to obtain desired performance when element 10 is transferred. Target substrate 2 may be provided with an alignment mark for the purpose of aligning element 10 and target substrate 2 when element 10 is picked up from source substrate 1 and transferred.

Stamp head 30 is, for example, a quadrangular plate-like table that is held on the lower surface of through hole 40a in the central portion of top plate 40b of frame 40 and holds stamp 3. As illustrated in FIG. 2, stamp head 30 may be of any type as long as it can hold stamp 3 having a side surface T-shape, in other words, a quadrangular plate shape in which central portion 3a protrudes downward in a quadrangular plate shape. Stamp head 30 may be provided with, for example, a suction hole for sucking stamp 3, and may apply a negative pressure to the suction hole to bring stamp 3 into close contact with stamp head 30.

Here, stamp 3 has viscoelasticity, and is a member for picking up element 10 formed on source substrate 1 by central portion 3a of stamp 3 by the viscoelasticity, that is, adhesive force, and transferring element 10 to a desired position on target substrate 2. Stamp 3 is silicone rubber or the like having viscoelasticity. Stamp 3 may be of any type as long as it has viscoelasticity. However, by making stamp 3 transparent, it is possible to simultaneously observe the positions of stamp 3 and element 10 or the positions of element 10 picked up by stamp 3 and target substrate 2 from above in the Z-axis direction when imaging is performed by imaging unit 60 described later. Stamp 3 may be provided with a protruding structure having the same size in the X-axis direction and the Y-axis direction as element 10 on a surface facing element 10, like the protruding central portion 3a. As a result, when element 10 and stamp 3 come into contact with each other, it is possible to prevent pickup of another element formed on source substrate 1. The protruding structure of stamp 3 is not limited to the same size as that of element 10 in the X-axis direction and the Y-axis direction, and may have a size larger than that of element 10 in the X-axis direction and the Y-axis direction, or may have a size smaller than that of element 10 in the X-axis direction and the Y-axis direction. By setting the dimension of the protruding structure of stamp 3 in the Z axis direction to be twice or more the dimension of element 10 in the Z axis direction, it is possible to easily prevent pickup of another element when element 10 and stamp 3 come into contact with each other.

Frame 40 is a member having a downward C-shape, and holds stamp head 30 at the position of the lower surface of through hole 40a in the central portion of top plate 40b. Imaging unit 60 to be described later is disposed above through hole 40a of frame 40, and imaging unit 60 images stamp head 30 side below through hole 40a, so that the relative position between stamp 3 and element 10 or the relative position between element 10 picked up by stamp 3 and target substrate 2 can be observed from above in the Z-axis direction. The material of frame 40 is stainless steel or the like.

Substrate stage 50 is a table disposed below top plate 40b of frame 40, and is supported by substrate position adjustment mechanism 51. Source substrate installation base 11 and target substrate installation base 21 are installed on the upper surface of substrate stage 50. Substrate stage 50 may be integrated with source substrate installation base 11 and target substrate installation base 21, or source substrate installation base 11 and target substrate installation base 21 may be fixed by screws or the like as separate members.

Substrate position adjustment mechanism 51 is a movable stage for adjusting the position of substrate stage 50 in the X-axis direction, the Y-axis direction, and the Z-axis direction. Specifically, substrate position adjustment mechanism 51 can adjust the position of substrate stage 50 in the X-axis direction and the Y-axis direction so that the relative positions in the X-axis direction and the Y-axis direction of element 10 of source substrate 1 installed on source substrate installation base 11 on substrate stage 50 and stamp 3 substantially coincide with each other at the time of pickup. In addition, substrate position adjustment mechanism 51 can adjust the position of substrate stage 50 in the X-axis direction and the Y-axis direction so that the relative positions in the X-axis direction and the Y-axis direction of target substrate 2 placed on target substrate installation base 21 on substrate stage 50 and element 10 picked up by stamp 3 substantially coincide with each other at the time of transfer. Further, substrate position adjustment mechanism 51 controls the position of substrate stage 50 in the Z-axis direction so that element 10 of source substrate 1 installed on source substrate installation base 11 on substrate stage 50 and stamp 3 can be brought into contact with and separated from each other at the time of pickup to perform a pickup operation. In addition, substrate position adjustment mechanism 51 controls the position of substrate stage 50 in the Z-axis direction so that target substrate 2 installed on target substrate installation base 21 on substrate stage 50 and element 10 picked up by stamp 3 can be brought into contact with and separated from each other at the time of transfer to perform a transfer operation. Substrate position adjustment mechanism 51 is realized by combining, for example, a linear motion stage using a linear ball guide, a gonio stage, or the like.

Imaging unit 60 to be described later is used to detect a positional shift during position adjustment of substrate stage 50. Substrate position adjustment mechanism 51 is configured to be movable in at least four axial directions different from each other. The four axis directions include an X-axis direction, a Y-axis direction, a Z-axis direction, and a rotation direction around the Z-axis. As a result, since fine operation can be realized in each step in the element transfer method described later, transfer accuracy is improved, and high-quality transfer can be realized. Note that the movable direction of substrate position adjustment mechanism 51 may be six axes of the X-axis direction, the Y-axis direction, the Z-axis direction, and rotation directions around these axes. Substrate position adjustment mechanism 51 is provided with a motor (not illustrated) and an encoder (not illustrated), and position information detected by the encoder (not illustrated) is input to controller C1.

Imaging unit 60 is a unit that is disposed above through hole 40a of frame 40 along the vertical direction, images stamp 3 and element 10 on source substrate 1, and images element 10 picked up by stamp 3 and target substrate 2, so that the positional deviation amount between stamp 3 and element 10 on source substrate 1 and the positional deviation amount between element 10 picked up by stamp 3 and target substrate 2 can be detected. Imaging unit 60 includes, for example, a lens and a camera, and information captured by the camera is input to controller C1, and calculator C2 of controller C1 calculates the positional deviation amount.

Imaging unit adjustment mechanism 61 is a movable stage for adjusting the position of imaging unit 60. Specifically, the position of imaging unit 60 is adjusted to a position where stamp 3 and element 10 on source substrate 1 can be observed by imaging unit 60 at the time of pickup, and element 10 picked up by stamp 3 at the time of transfer and target substrate 2 can be observed by imaging unit 60. Imaging unit adjustment mechanism 61 is realized by combining, for example, a linear motion stage using a linear ball guide. Imaging unit adjustment mechanism 61 is configured to be movable in at least three axial directions different from each other. The triaxial direction includes an X-axis direction, a Y-axis direction, and a Z-axis direction. Imaging unit adjustment mechanism 61 is provided with a motor (not illustrated) and an encoder (not illustrated), and position information detected by the encoder (not illustrated) is input to controller C1.

As illustrated in FIG. 2, contact detector 70 is a sensor that is disposed between stamp head 30 and vibrator 80 to be described later and detects contact of stamp 3. Specifically, for example, contact between stamp 3 and element 10 on source substrate 1 at the time of pickup and contact between element 10 picked up on stamp 3 and target substrate 2 at the time of transfer are detected. Contact detector 70 is, for example, a piezoelectric force sensor. Voltage and force information measured by contact detector 70 are input to controller C1. By monitoring the force information detected by contact detector 70 by controller C1, the position of substrate stage 50 in the Z-axis direction can be adjusted, and excessive pressure application to element 10 can be detected by controller C1, so that breakage of element 10 can be prevented.

As illustrated in FIG. 2, vibrator 80 is a unit that is disposed between contact detector 70 and frame 40 and applies vibration to stamp 3 via contact detector 70. Specifically, when element 10 picked up on stamp 3 at the time of transfer and target substrate 2 are separated in the Z-axis direction by substrate position adjustment mechanism 51, vibration is applied to stamp 3 and element 10 picked up on stamp 3 via contact detector 70. Vibrator 80 generates arbitrary vibration having a frequency of 10 [Hz] to 100 [kHz] and an amplitude of 10 [nm] to 10 [μm], for example, and is an actuator using a piezoelectric element utilizing a piezoelectric effect, for example. Vibrator 80 is configured to generate vibration in, for example, the X-axis direction and the Y-axis direction, that is, vibration direction A and vibration direction B illustrated in FIG. 2, and is preferably configured to generate vibration in three axial directions different from each other. The three axial directions include an X-axis direction, a Y-axis direction, and a Z-axis direction, and are indicated by a vibration direction A, a vibration direction B, and a vibration direction C, respectively, in FIG. 2. Furthermore, vibrator 80 is controlled by controller C1 to apply vibration to stamp 3 and element 10 of stamp 3.

Controller C1 is a microcomputer or the like that controls the operation of members constituting element transfer device D1, and includes calculator C2 that executes various calculations, for example, calculation of a positional deviation amount from imaged information. Controller C1 controls imaging unit adjustment mechanism 61 such that stamp 3 and element 10 on source substrate 1 can be observed at the time of pickup and element 10 and target substrate 2 picked up on stamp 3 can be observed at the time of transfer by imaging with imaging unit 60. In addition, controller C1 controls substrate position adjustment mechanism 51 such that the positional deviation amounts in the X-axis direction and the Y-axis direction between stamp 3 and element 10 detected by imaging unit 60 at the time of pickup and the positional deviation amounts in the X-axis direction and the Y-axis direction between element 10 picked up by stamp 3 and target substrate 2 at the time of transfer each approach 0 as much as possible. In addition, controller C1 detects the contact between stamp 3 and element 10 on source substrate 1 at the time of pickup and the contact between element 10 picked up on stamp 3 and target substrate 2 at the time of transfer based on the force information detected by contact detector 70, and controls substrate position adjustment mechanism 51. In addition, controller C1 controls vibrator 80 so as to apply vibration to the elements 10 of stamp 3 and stamp 3 in a state of detecting contact between element 10 picked up by stamp 3 and target substrate 2 at the time of transfer.

Element transfer method

Next, the method for transferring element 10 is performed at least in the following steps S101 to S105.

First, in step S101, controller C1 controls the operation of substrate position adjustment mechanism 51 on the basis of the information imaged by imaging unit 60 to align the positions of element 10 and stamp 3 on source substrate 1 (corresponding to step S10 described below).

Next, in step S102, controller C1 controls the operation of substrate position adjustment mechanism 51 to relatively move source substrate 1 and stamp 3 closer to and away from each other, and pick up element 10 on stamp 3 with the adhesive force of stamp 3 (Corresponding to following steps S20, S21, and S30).

Next, in step S103, controller C1 controls the operation of substrate position adjustment mechanism 51 on the basis of the information imaged by imaging unit 60 to align the positions of target substrate 2 and element 10 of stamp 3 (corresponding to step S40 described below).

Next, in step S104, controller C1 controls the operation of substrate position adjustment mechanism 51 to bring target substrate 2 and stamp 3 relatively close to each other and bring element 10 of stamp 3 into contact with target substrate 2 (Corresponding to following steps S50 and S51).

Next, in step S105, controller C1 controls the operation of substrate position adjustment mechanism 51 to relatively separate target substrate 2 and stamp 3 and transfers element 10 from stamp 3 to target substrate 2 while applying vibration to element 10 of stamp 3 and stamp 3 by vibrator 80 (Corresponding to following steps S60 and S70).

These steps are described in detail below.

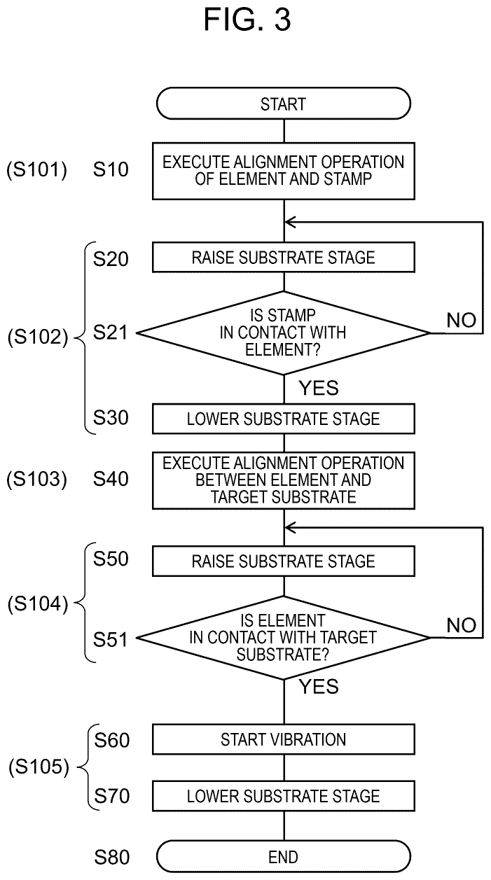

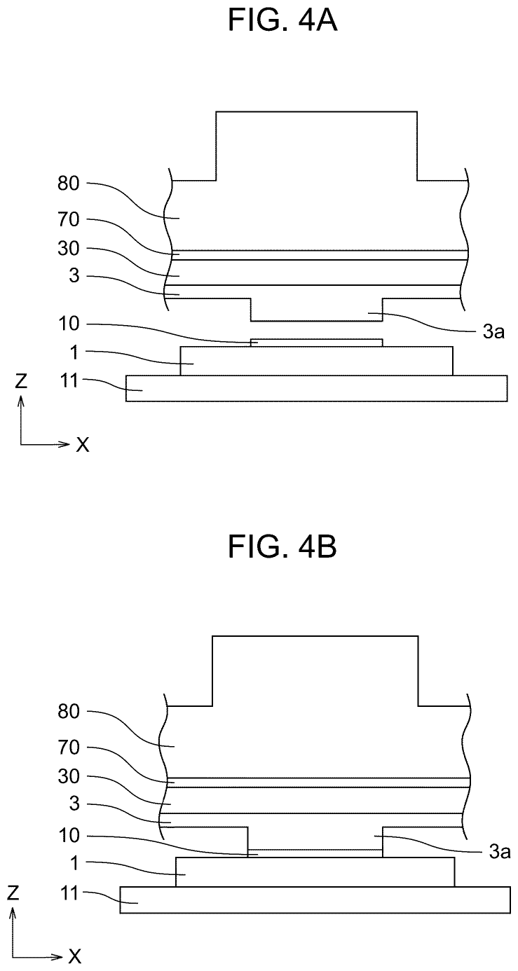

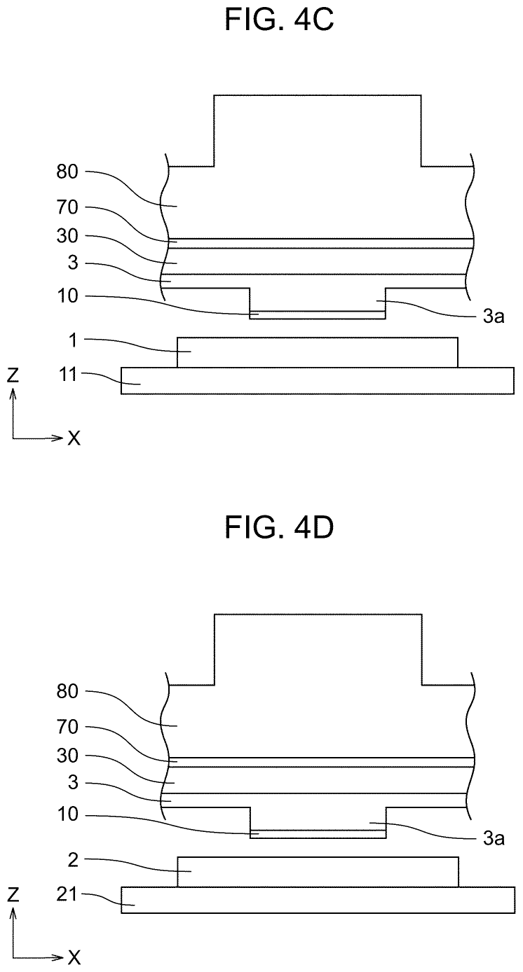

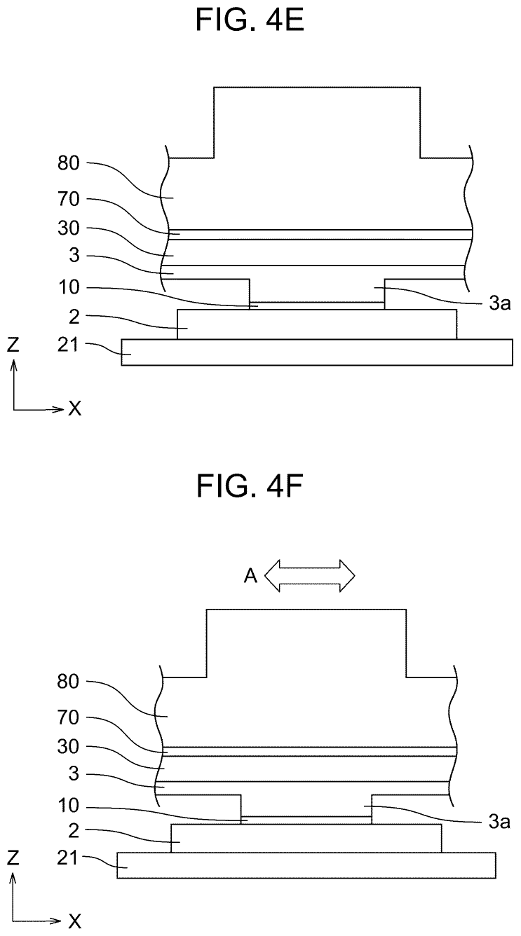

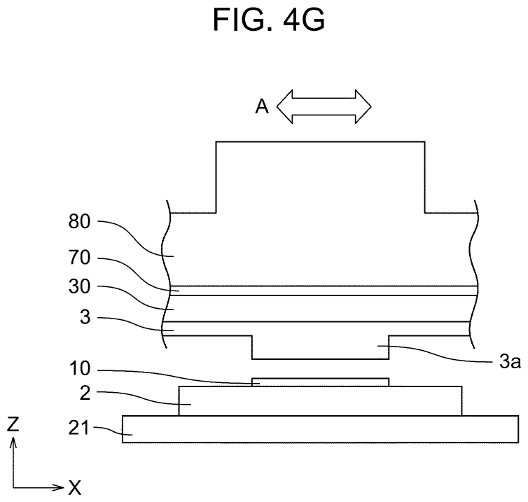

With reference to FIGS. 3, 4A, 4B, 4C, 4D, 4E, 4F, and 4G, an element transfer method according to the exemplary embodiment of the present disclosure using element transfer device D1 will be described. FIG. 3 is a flowchart illustrating an element transfer method according to the exemplary embodiment of the present disclosure, and FIGS. 4A, 4B, 4C, 4D, 4E, 4F, and 4G are diagrams for describing the element transfer method according to the exemplary embodiment of the present disclosure.

First, as illustrated in FIG. 4A, an alignment operation between element 10 and stamp 3 is executed (step S10). In step S10, source substrate 1 is installed on source substrate installation base 11, and target substrate 2 is installed on target substrate installation base 21.

Here, the alignment operation is to move substrate stage 50 to a predetermined position on the XY plane by controlling the operation of substrate position adjustment mechanism 51 by controller C1. The predetermined position in step S10 is, for example, the position of substrate stage 50 at which the positions of element 10 and stamp 3 on source substrate 1 coincide with each other in the XY plane. Here, the fact that the positions of element 10 and stamp 3 coincide with each other means a case where the alignment marks coincide with each other or the outer shapes coincide with each other. Therefore, in step S10, imaging unit 60 images element 10 and stamp 3 on source substrate 1, and calculator C2 calculates and detects the positional deviation amount between element 10 and stamp 3 on source substrate 1 with respect to a predetermined position on the basis of the imaged information, and substrate position adjustment mechanism 51 adjusts the position of substrate stage 50 under the control of controller C1 so as to reduce the positional deviation amount on the basis of the detected positional deviation amount. By adjusting the position of substrate stage 50, the position of source substrate 1 is adjusted, and the position of element 10 on source substrate 1 is adjusted. Furthermore, in a case where the position of imaging unit 60 needs to be adjusted, the position of imaging unit 60 may be adjusted by imaging unit adjustment mechanism 61 under the control of controller C1. The position adjustment accuracy of substrate position adjustment mechanism 51 by the operation in step S10 is on the order of nanometers. Note that, the accuracy of position adjustment in the operation of step S10 is not limited to the order of nanometers, and may be executed in the order of micrometers. FIG. 4A illustrates a state in which the alignment operation between element 10 and stamp 3 is completed.

Next, as illustrated in FIG. 4B, substrate stage 50 is raised (step S20). For raising substrate stage 50, substrate position adjustment mechanism 51 is used under the control of controller C1. As substrate stage 50 rises, the distance between element 10 on source substrate 1 and stamp 3 in the Z-axis direction decreases. After substrate stage 50 starts to rise, when controller C1 determines that contact detector 70 has not detected the contact between element 10 and stamp 3 on the basis of the detection information in contact detector 70 (step S21, NO), substrate stage 50 continues to rise by substrate position adjustment mechanism 51 under the control of controller C1. When controller C1 determines that contact detector 70 has detected the contact between element 10 and stamp 3 based on the detection information in contact detector 70 (YES in step S21), substrate position adjustment mechanism 51 stops raising substrate stage 50 under the control of controller C1.

Here, the threshold at which contact detector 70 determines the contact is appropriately set according to the physical properties, the shape, and the like of element 10 and stamp 3. For example, in a case where a piezoelectric force sensor is used as contact detector 70, the threshold for determining that the contact is made is 1 [nN] to 10 [N]. In step S20, the rising speed of substrate stage 50 by substrate position adjustment mechanism 51 under the control of controller C1 is, for example, 1 [nm/sec] to 1000 [μm/sec]. Note that by lowering the threshold value for determining that the contact is made by contact detector 70 or by lowering the rising speed of substrate stage 50, it is possible to suppress excessive rising of substrate stage 50, and thus, it is possible to prevent breakage of element 10. FIG. 4B illustrates a state in which substrate stage 50 is raised and element 10 and stamp 3 are in contact with each other.

Next, as illustrated in FIG. 4C, substrate stage 50 is lowered (step S30). For lowering substrate stage 50, substrate position adjustment mechanism 51 is used under the control of controller C1. By lowering substrate stage 50 under the control of controller C1 in a state where element 10 and stamp 3 are in contact with each other, element 10 is peeled off from source substrate 1 by the adhesive force of stamp 3 and is picked up by stamp 3. Here, the adhesive force of stamp 3 is appropriately selected depending on the physical properties of element 10 and target substrate 2 to be described later. In step S30, the lowering speed of substrate stage 50 by substrate position adjustment mechanism 51 under the control of controller C1 is, for example, 10 [μm/sec] to 1000 [mm/sec]. It is known that the adhesive force of the viscoelastic material such as stamp 3 increases depending on the peeling speed in some speed regions. Therefore, as the lowering speed of substrate stage 50 is increased in a state where element 10 and stamp 3 are in contact with each other, the adhesive force of stamp 3 is increased, and the force for peeling element 10 from source substrate 1 is increased. That is, element 10 can be easily picked up on stamp 3. FIG. 4C illustrates a state in which substrate stage 50 that has been raised is lowered after the contact between element 10 and stamp 3 is detected.

Next, as shown in FIG. 4D, the alignment operation of element 10 and target substrate 2 is executed (step S40). Here, the alignment operation is to move substrate stage 50 to a predetermined position on the XY plane by controlling the operation of substrate position adjustment mechanism 51 by controller C1. The predetermined position in step S40 is, for example, the position of substrate stage 50 where the positions of target substrate 2 and element 10 picked up by stamp 3 coincide with each other in the XY plane. Here, the fact that the positions of target substrate 2 and element 10 coincide with each other means a case where alignment marks coincide with each other or outer shapes coincide with each other. Therefore, in step S40, imaging unit 60 images target substrate 2 and element 10 picked up by stamp 3, and calculator C2 calculates and detects the positional deviation amount between target substrate 2 and element 10 picked up by stamp 3 with respect to a predetermined position on the basis of the imaged information, and substrate position adjustment mechanism 51 adjusts the position of substrate stage 50 under the control of controller C1 so as to reduce the positional deviation amount on the basis of the detected positional deviation amount. The position of target substrate 2 is adjusted by adjusting the position of substrate stage 50. Furthermore, in a case where the position of imaging unit 60 needs to be adjusted, the position of imaging unit 60 may be adjusted by imaging unit adjustment mechanism 61 under the control of controller C1. The position adjustment accuracy of substrate position adjustment mechanism 51 by the operation in step S40 is on the order of nanometers. Note that, the accuracy of position adjustment in the operation of step S40 is not limited to the order of nanometers, and may be executed in the order of micrometers. FIG. 4D illustrates a state in which the alignment operation of target substrate 2 and element 10 picked up by stamp 3 is completed.

Next, as illustrated in FIG. 4E, substrate stage 50 is raised (step S50). As substrate stage 50 rises, the distance between target substrate 2 and element 10 picked up by stamp 3 in the Z-axis direction decreases. After substrate stage 50 starts to rise, when controller C1 determines that contact detector 70 has not detected the contact between target substrate 2 and element 10 picked up by stamp 3 based on the detection information in contact detector 70 (step S51, NO), substrate stage 50 continues to rise by substrate position adjustment mechanism 51 under the control of controller C1. When controller C1 determines that contact detector 70 detects the contact between target substrate 2 and element 10 picked up by stamp 3 based on the detection information in contact detector 70 (YES in step S51), substrate position adjustment mechanism 51 stops raising substrate stage 50 under the control of controller C1. The threshold at which contact detector 70 determines that target substrate 2, stamp 3, and element 10 are in contact with each other is appropriately set in accordance with mechanical properties, shapes, and the like of target substrate 2, stamp 3, and element 10. For example, in a case where a piezoelectric force sensor is used as contact detector 70, the threshold for determining that the contact is made is 1 [nN] to 10 [N]. In step S50, the rising speed of substrate stage 50 by substrate position adjustment mechanism 51 is, for example, 1 [nm/sec] to 1000 [μm/sec]. Note that by lowering the threshold value for determining that the contact is made by contact detector 70 or by lowering the rising speed of substrate stage 50, it is possible to suppress excessive rising of substrate stage 50, and thus, it is possible to prevent breakage of element 10. FIG. 4E illustrates a state in which substrate stage 50 is raised and target substrate 2 and element 10 picked up by stamp 3 are in contact with each other. Here, the state in which element 10 picked up by stamp 3 is in contact with target substrate 2 means that the pushing amount by which element 10 is pushed and held in contact with target substrate 2 is larger than the amplitude of vibration in the Z axis direction described below, so that element 10 is not separated from target substrate 2 even if vibration is applied. Under such a dimensional relationship, as an example, when the amplitude of the vibration by vibrator 80 is 10 [nm] to 10 [μm], the amount by which element 10 is pushed into target substrate 2 via stamp 3 is, for example, 1 [μm] to 50 [μm]. By making the amount by which element 10 is pushed into target substrate 2 via stamp 3 smaller than the dimension of the protruding structure of stamp 3 in the Z-axis direction, it is possible to prevent contamination of target substrate 2 or stamp 3 caused by contact of a portion other than the protruding structure of stamp 3 with target substrate 2.

Next, in a state where target substrate 2 and element 10 picked up by stamp 3 are in contact with each other, as illustrated in FIG. 4F, the vibration of stamp 3 and element 10 of stamp 3 is started by vibrator 80 (step S60). When the vibration direction is the X-axis direction, that is, vibration direction A, stress in the shear direction acts on the interface between target substrate 2 and element 10. The main factor of the adhesive force acting on the interface between stamp 3 and element 10 is the van der Waals force. However, in the van der Waals coupling, the coupling is more easily broken when a shear force acting in the lateral direction, for example, the horizontal direction, that is, the X-axis direction and the Y-axis direction is applied as compared with a tensile force in the vertical direction, that is, the Z-axis direction. Therefore, even in a case where the force acting on target substrate 2 and element 10 is weak when substrate stage 50 is lowered to relatively separate target substrate 2 and stamp 3 in step S70 to be described later, the van der Waals coupling generated at the interface between stamp 3 and element 10 can be cut by applying vibration to element 10 of stamp 3 and stamp 3 by vibrator 80, so that element 10 can be reliably transferred to target substrate 2 in a state where the adhesive force is reduced. Similarly, even when the vibration direction is the Y-axis direction, that is, vibration direction B illustrated in FIG. 2, stress in the shear direction acts on the interface between target substrate 2 and element 10. In addition, in a case where the vibration direction is the Z-axis direction, that is, vibration direction C illustrated in FIG. 2, stress in the tensile direction acts on the interface between target substrate 2 and element 10, and in addition to the force in the tensile direction acting when substrate stage 50 is lowered to relatively separate target substrate 2 and stamp 3 in step S70 described later, stress control in the tensile direction by vibration can cut the van der Waals coupling generated at the interface between stamp 3 and element 10, so that element 10 can be easily transferred to target substrate 2 in a state where the adhesive force is reduced. Vibration direction by vibrator 80 may be any one of the X-axis direction, the Y-axis direction, and the Z-axis direction, that is, vibration direction A, vibration direction B, and vibration direction C illustrated in FIG. 2, but when substrate stage 50 is lowered in step S70 described later, element 10 can be more easily transferred to target substrate 2 by simultaneously applying vibration in vibration direction A and vibration direction B. Furthermore, by setting vibration direction By vibrator 80 to all of the X-axis direction, the Y-axis direction, and the Z-axis direction, that is, vibration direction A, vibration direction B, and vibration direction C illustrated in FIG. 2, the stress generated at the interface between stamp 3 and element 10 can be used as the cleavage stress, so that the adhesive force can be further locally reduced, and element 10 can be stably and easily transferred to target substrate 2. Furthermore, in a region where the frequency of vibration by vibrator 80 is small, vibration is absorbed due to the fact that stamp 3 is a viscoelastic body. On the other hand, in a region where the frequency of vibration by vibrator 80 is too large, stamp 3 is heated by the vibration, and thus, there is a risk that the stamp material may be deteriorated. Therefore, the vibration by vibrator 80 only needs to have a frequency of 10 [Hz] to 100 [kHz], and preferably, by setting the frequency to 500 [Hz] to 50 [kHz], the effect of stress control by vibration can be more stably obtained, and element 10 can be reliably transferred to target substrate 2. Furthermore, in a region where the amplitude of vibration by vibrator 80 is small, vibration is absorbed due to the fact that stamp 3 is made of a viscoelastic material. On the other hand, in a region where the amplitude of the vibration by vibrator 80 is large, element 10 may be damaged by the vibration. Therefore, the vibration by vibrator 80 only needs to have an amplitude of 10 [nm] to 10 [μm], and preferably, by setting the amplitude to 10 [nm] to 1 [μm], the effect of stress control by vibration can be more stably obtained, and element 10 can be reliably transferred to target substrate 2. Furthermore, vibrator 80 may be operated such that at least one of the frequency and the amplitude of vibration becomes non-uniform by operating at least one of the vibration directions at a frequency or an amplitude different from the others. FIG. 4F illustrates a state in which vibration is applied to stamp 3 and element 10 of stamp 3 by vibrator 80 after the contact between target substrate 2 and element 10 of stamp 3 is detected.

As a specific example, if the amplitude in the X-axis direction or the Y-axis direction parallel to the direction of the length with a large aspect ratio of the outer shape of element 10 (for example, the direction along the long side of the rectangle or the long axis of the ellipse) is made larger than the amplitude in the Y-axis direction or the X-axis direction parallel to the direction of the length with a small aspect ratio (for example, the direction along the short side of the rectangle or the short axis of the ellipse), the adhesive force can be more easily reduced. This is because, in the direction of the length having a large aspect ratio with respect to the direction of the length having a small aspect ratio, the action of elastic deformation of stamp 3 is also large, the amplitude of vibration is more absorbed by stamp 3, and the shearing force generated at the interface between stamp 3 and element 10 becomes small. When the amplitude is increased, in order to practically exhibit the effect of reducing the adhesive force, the amplitude is preferably increased by at least about 10%, and, with the aspect ratio of the outer shape of element 10 or more, that is, the aspect ratio being 2, the amplitude is more preferably increased by 200% or more.

Next, as illustrated in FIG. 4G, substrate stage 50 is lowered (step S70). Under the control of controller C1, substrate stage 50 is lowered in a state where target substrate 2 and element 10 picked up by stamp 3 are in contact with each other and in a state where vibration is applied to element 10 of stamp 3 and stamp 3 by vibrator 80, whereby element 10 is peeled off from stamp 3 and transferred to target substrate 2 by the adhesion force between target substrate 2 and element 10. In step S70, the lowering speed of substrate stage 50 by substrate position adjustment mechanism 51 is, for example, 1 [nm/sec] to 100 [μm/sec]. It is known that the adhesive force of the viscoelastic material such as stamp 3 increases depending on the peeling speed in some speed regions. Therefore, as the lowering speed of substrate stage 50 is reduced in a state where target substrate 2 and element 10 of stamp 3 are in contact with each other, the adhesive force of stamp 3 becomes weaker, and the force with which stamp 3 can hold element 10 becomes weaker. However, since the effect of the lowering speed is limited, in step S60, the vibration is applied to element 10 of stamp 3 and stamp 3 by vibrator 80 to reduce the adhesive force acting on stamp 3 and element 10, so that the transfer can be reliably performed even when the force acting on target substrate 2 and element 10 is weak. FIG. 4G illustrates a state where the ascending substrate stage 50 is lowered in a state where vibration is applied to stamp 3 and element 10 of stamp 3 by vibrator 80.

Through the above steps, the transfer of element 10 is realized.

As described above, in the transfer of element 10, by applying vibration in at least one of vibration direction A, vibration direction B, and vibration direction C illustrated in FIG. 2 to element 10 of stamp 3 and stamp 3 by vibrator 80 in step S60, the stress at the interface between stamp 3 and element 10 of stamp 3 is controlled, and element 10 can be reliably transferred to target substrate 2 in a state where the adhesive force acting on element 10 of stamp 3 and stamp 3 is reduced.

Therefore, according to the above exemplary embodiment, the plasma treatment and the heat treatment are unnecessary, and by reducing the adhesive force at the time of transferring the element with the simple configuration including vibrator 80, it is possible to prevent element 10 from falling off and remaining from stamp 3 and to realize high-quality, that is, highly accurate and reliable transfer of element 10 to target substrate 2.

Note that, by appropriately combining arbitrary exemplary embodiments or modifications among the various exemplary embodiments or modifications described above, the effects of the respective exemplary embodiments or modifications can be achieved. In addition, combinations of exemplary embodiments, combinations of examples, or combinations of exemplary embodiments and examples are possible, and combinations of features in different exemplary embodiments or examples are also possible.

Although the present disclosure has been fully described in connection with preferable exemplary embodiments with reference to the accompanying drawings, various modifications or corrections are obvious to those skilled in the art. Such variations or modifications are to be understood as being included within the scope of the present disclosure as set forth in the appended scope of claims, as long as such variations and modifications do not depart from the scope of the present disclosure. In addition, changes in the combination or the order of elements in the exemplary embodiment can be achieved without departing from the scope and ideas of the present disclosure.

### Supplementary Note

The above description of the exemplary embodiments discloses the following techniques.

(Technique 1) An element transfer method including:
aligning positions of a target substrate and an element picked up by an adhesive force of a stamp;
bringing the target substrate and the stamp relatively close to each other to bring the target substrate and the element into contact with each other; and
transferring the element from the stamp to the target substrate by relatively separating the target substrate and the stamp while applying vibration to the stamp and the element by a vibrator.

(Technique 2) The element transfer method according to Technique 1, further including, before the aligning, bringing a source substrate having the element and the stamp relatively close to each other and separating the source substrate having the element and the stamp, to pick up the element of the source substrate on the stamp with the adhesive force of the stamp.

(Technique 3) The element transfer method according to Technique 1 or 2, in which
the bringing the target substrate and the stamp relatively close to each other to bring the target substrate and the element into contact with each other includes detecting contact between the target substrate and the element by a contact detector, and
the relatively separating the target substrate and the stamp while applying vibration to the stamp and the element by the vibrator includes applying vibration in at least one of an X-axis direction, a Y-axis direction, and a Z-axis direction of the stamp and the element by the vibrator.

(Technique 4) The element transfer method according to Technique 3, in which
the bringing the target substrate and the stamp relatively close to each other to bring the target substrate and the element into contact with each other includes pushing the element into the target substrate by a predetermined pushing amount,
the vibration by the vibrator has an amplitude in the Z-axis direction, and
the amplitude in the Z-axis direction is smaller than the predetermined pushing amount.

(Technique 5) The element transfer method according to any one of Techniques 1 to 4, in which a frequency of vibration by the vibrator is 10 Hz to 100 kHz, and the amplitude of vibration by the vibrator is 10 nm to 10 μm.

(Technique 6) An element transfer device including:
a target substrate installation base on which a target substrate is installed;
a stamp head including a stamp configured to pick up an element with adhesive force;
a frame that holds the stamp head in which the stamp faces the target substrate installation base;
a substrate position adjustment mechanism configured to adjust a position of the target substrate with respect to the stamp and bring the target substrate and the stamp relatively close to each other and separates the target substrate and the stamp;
an imaging unit configured to capture an image of the element and the stamp and capture an image of the element and the target substrate, to enable detection of a positional deviation amount between the element and the stamp and a positional deviation amount between the element and the target substrate, respectively;
a contact detector configured to detect contact between the element and the target substrate;
a vibrator that is disposed between the contact detector and the frame and configured to apply vibration to the stamp and the element; and
a controller configured to control the vibrator and the substrate position adjustment mechanism so as to transfer the element from the stamp to the target substrate by:
(a) controlling the substrate position adjustment mechanism so as to reduce the positional deviation amounts,
(b) controlling the substrate position adjustment mechanism so as to bring the target substrate and the stamp relatively closer,
(c) detecting that the target substrate and the element of the stamp are in contact with each other by the contact detector,
(d) controlling the vibrator so as to apply vibration to the stamp and the element, and
(e) relatively separating the target substrate and the stamp while applying vibration to the stamp and the element.

(Technique 7) The element transfer device according to Technique 6, further including a source substrate installation base on which a source substrate on which the element is formed is installed,
in which
the frame holds the stamp head in which the stamp also faces the source substrate installation base,
the substrate position adjustment mechanism is configured to adjust a position of the source substrate with respect to the stamp and bring the source substrate and the stamp relatively close to each other and separates the source substrate and the stamp,
the contact detector is configured to detect contact between the element and the stamp, and
the controller is configured to control the substrate position adjustment mechanism so as to relatively bring close and separate the source substrate and the stamp to pick up the element on the stamp with the adhesive force of the stamp.

(Technique 8) The element transfer device according to Technique 7, in which
the controller causes the contact detector to detect contact between the element and the stamp when the element is picked up on the stamp with the adhesive force of the stamp, and
the controller controls the vibrator to apply vibration to the stamp and the element in at least one of an X-axis direction, a Y-axis direction, and a Z-axis direction when the element is transferred from the stamp to the target substrate.

(Technique 9) The element transfer device according to Technique 8, in which
the controller controls the substrate position adjustment mechanism so as to push the element into the target substrate by a predetermined pushing amount when the target substrate and the stamp are brought relatively close to each other,
the vibration by the vibrator has an amplitude in the Z-axis direction, and
the amplitude in the Z-axis direction is smaller than the predetermined pushing amount.

(Technique 10) The element transfer device according to any one of Techniques 6 to 9, in which the vibrator is configured to generate arbitrary vibration having a frequency of 10 Hz to 100 kHz and an amplitude of 10 nm to 10 μm.

According to each of these techniques, it is possible to realize highly accurate and reliable transfer of an element by reducing the adhesive force at the time of transferring the element with a simple configuration in which neither plasma treatment nor heat treatment is required, and a vibrator for applying vibration to an element and a stamp is provided to perform vibration.

### INDUSTRIAL APPLICABILITY

An embodiment of the present disclosure can be suitably applied to an element transfer method and an element transfer device. In addition, since the element transfer method and the element transfer device according to the above-described aspect of the present disclosure can transfer an optical element to a target substrate with high accuracy, for example, the element transfer method and the element transfer device can be applied in the fields of high-speed optical communication typified by a micro LED display or silicon photonics, high-accuracy sensing using laser light, and the like.

### REFERENCE MARKS IN THE DRAWINGS

1 source substrate
2 target substrate
3 stamp
3a central portion
10 element
11 source substrate installation base
21 target substrate installation base
30 stamp head
40 frame
40a through hole
40b top plate
50 substrate stage
51 substrate position adjustment mechanism
60 imaging unit
61 imaging unit adjustment mechanism
70 contact detector
80 vibrator
C1 controller
C2 calculator
D1 element transfer device

1. An element transfer method comprising:
aligning positions of a target substrate and an element picked up by an adhesive force of a stamp;
bringing the target substrate and the stamp relatively close to each other to bring the target substrate and the element into contact with each other; and
transferring the element from the stamp to the target substrate by relatively separating the target substrate and the stamp while applying vibration to the stamp and the element by a vibrator.

2. The element transfer method according to claim 1, further comprising, before the aligning, bringing a source substrate having the element and the stamp relatively close to each other and separating the source substrate having the element and the stamp, to pick up the element of the source substrate on the stamp with the adhesive force of the stamp.

3. The element transfer method according to claim 1, wherein
the bringing the target substrate and the stamp relatively close to each other to bring the target substrate and the element into contact with each other includes detecting contact between the target substrate and the element by a contact detector, and
the relatively separating the target substrate and the stamp while applying vibration to the stamp and the element by the vibrator includes applying vibration in at least one of an X-axis direction, a Y-axis direction, and a Z-axis direction of the stamp and the element by the vibrator.

4. The element transfer method according to claim 3, wherein
the bringing the target substrate and the stamp relatively close to each other to bring the target substrate and the element into contact with each other includes pushing the element into the target substrate by a predetermined pushing amount,
the vibration by the vibrator has an amplitude in the Z-axis direction, and
the amplitude in the Z-axis direction is smaller than the predetermined pushing amount.

5. The element transfer method according to claim 1, wherein a frequency of vibration by the vibrator is 10 Hz to 100 kHz, and the amplitude of vibration by the vibrator is 10 nm to 10 μm.

6. An element transfer device comprising:
a target substrate installation base on which a target substrate is installed;
a stamp head including a stamp configured to pick up an element with adhesive force;
a frame that holds the stamp head in which the stamp faces the target substrate installation base;
a substrate position adjustment mechanism configured to adjust a position of the target substrate with respect to the stamp and bring the target substrate and the stamp relatively close to each other and separates the target substrate and the stamp;
an imaging unit configured to capture an image of the element and the stamp and capture an image of the element and the target substrate, to enable detection of a positional deviation amount between the element and the stamp and a positional deviation amount between the element and the target substrate, respectively;
a contact detector configured to detect contact between the element and the target substrate;
a vibrator that is disposed between the contact detector and the frame and configured to apply vibration to the stamp and the element; and
a controller configured to control the vibrator and the substrate position adjustment mechanism so as to transfer the element from the stamp to the target substrate by:
(a) controlling the substrate position adjustment mechanism so as to reduce the positional deviation amounts,
(b) controlling the substrate position adjustment mechanism so as to bring the target substrate and the stamp relatively closer,
(c) detecting that the target substrate and the element are in contact with each other by the contact detector,
(d) controlling the vibrator so as to apply vibration to the stamp and the element, and
(e) relatively separating the target substrate and the stamp while applying vibration to the stamp and the element.

7. The element transfer device according to claim 6, further comprising a source substrate installation base on which a source substrate on which the element is formed is installed,
wherein
the frame holds the stamp head in which the stamp also faces the source substrate installation base,
the substrate position adjustment mechanism is configured to adjust a position of the source substrate with respect to the stamp and bring the source substrate and the stamp relatively close to each other and separates the source substrate and the stamp,
the contact detector is configured to detect contact between the element and the stamp, and
the controller is configured to control the substrate position adjustment mechanism so as to relatively bring close and separate the source substrate and the stamp to pick up the element on the stamp with the adhesive force of the stamp.

8. The element transfer device according to claim 7, wherein
the controller causes the contact detector to detect contact between the element and the stamp when the element is picked up on the stamp with the adhesive force of the stamp, and
the controller controls the vibrator to apply vibration to the stamp and the element in at least one of an X-axis direction, a Y-axis direction, and a Z-axis direction when the element is transferred from the stamp to the target substrate.

9. The element transfer device according to claim 8, wherein
the controller controls the substrate position adjustment mechanism so as to push the element into the target substrate by a predetermined pushing amount when the target substrate and the stamp are brought relatively close to each other,
the vibration by the vibrator has an amplitude in the Z-axis direction, and
the amplitude in the Z-axis direction is smaller than the predetermined pushing amount.

10. The element transfer device according to claim 6, wherein the vibrator is configured to generate arbitrary vibration having a frequency of 10 Hz to 100 kHz and an amplitude of 10 nm to 10 μm.
